(19) United States
(12) Patent Application Publication
(10) Pub. No.: US 2021/0043545 A1
(43) Pub. Date: Feb. 11, 2021

(54) SEMICONDUCTOR DEVICE AND MANUFACTURING METHOD THEREOF

(71) Applicant: NANYA TECHNOLOGY CORPORATION, New Taipei city (TW)

(72) Inventors: Sheng-Fu HUANG, New Taipei City (TW); Shing-Yih SHIH, New Taipei City (TW)

(21) Appl. No.: 16/535,060

(22) Filed: Aug. 7, 2019

(51) Int. Cl. H01L 23/48; H01L 23/00; H01L 21/768; H01L 25/00

(52) U.S. Cl. CPC H01L 23/481; H01L 24/32; H01L 21/76898; H01L 24/83; H01L 2224/0557; H01L 24/05; H01L 2224/32145; H01L 2224/8389; H01L 25/00

(57) ABSTRACT

A semiconductor device includes a first semiconductor wafer, a second semiconductor wafer, and a first conductive via. The first semiconductor wafer includes a first substrate and at least one first conductive layer disposed on a top surface of the first substrate. The second semiconductor wafer is disposed on the first semiconductor wafer. The second semiconductor wafer includes a second substrate and a first conductive pad disposed on a top surface of the second substrate. The first conductive via extends from the first conductive pad to the first conductive layer.

### BACKGROUND

### Field of Invention

The present disclosure relates to a semiconductor device and a manufacturing method of the semiconductor device.

### Description of Related Art

In recent years, the semiconductor industry has experienced rapid growth due to continuous improvements in the integration density of various electronic components (i.e., transistors, diodes, resistors, or capacitors). The improvement in integration density has come from repeated reductions in minimum feature size, which allows more components to be integrated into a given area.

### SUMMARY

The present disclosure relates in general to a semiconductor device and a manufacturing method thereof.

According to an embodiment of the present disclosure, a semiconductor device includes a first semiconductor wafer, a second semiconductor wafer, and a first conductive via. The first semiconductor wafer includes a first substrate and at least one first conductive layer disposed on a top surface of the first substrate. The second semiconductor wafer is disposed on the first semiconductor wafer. The second semiconductor wafer includes a second substrate and a first conductive pad disposed on a top surface of the second substrate. The first conductive via extends from the first conductive pad to the first conductive layer.

In an embodiment of the present disclosure, the first semiconductor wafer further includes a first insulating layer. The first insulating layer is disposed on the top surface of the first substrate, and a top surface of the first conductive layer is substantially coplanar with a top surface of the first insulating layer.

In an embodiment of the present disclosure, the first semiconductor wafer further includes a second conductive pad disposed on a bottom surface of the first substrate. The semiconductor device further includes a second conductive via extending from the first conductive layer to the second conductive pad.

In an embodiment of the present disclosure, the first semiconductor wafer further includes a first molding layer and a first molding layer. The first molding layer is disposed on the bottom surface of the first substrate, and a bottom surface of the second conductive pad is substantially coplanar with a bottom surface of the first molding layer. The first redistribution layer is disposed on the bottom surface of the first molding layer, and the second conductive pad is in contact with the first redistribution layer.

In an embodiment of the present disclosure, the first semiconductor wafer includes a plurality of the first conductive layers. The first conductive layers are stacked on the top surface of the first substrate.

In an embodiment of the present disclosure, the first semiconductor wafer further includes a plurality of first interconnecting structures. The first interconnecting structures are respectively disposed between the first conductive layers.

In an embodiment of the present disclosure, the second semiconductor wafer further includes at least one second conductive layer disposed on a bottom surface of the second substrate. The semiconductor device further includes a third conductive via extending from the first conductive pad to the second conductive layer.

In an embodiment of the present disclosure, the second semiconductor wafer further includes a second insulating layer. The second insulating layer is disposed on the bottom surface of the second substrate, and a bottom surface of the second conductive layer is substantially coplanar with a bottom surface of the second insulating layer.

In an embodiment of the present disclosure, the second semiconductor wafer includes a plurality of the second conductive layers. The second conductive layers are stacked on the bottom surface of the second substrate.

In an embodiment of the present disclosure, the second semiconductor wafer further includes a plurality of second interconnecting structures. The second interconnecting structures are respectively disposed between the second conductive layers.

In an embodiment of the present disclosure, the second semiconductor wafer further includes a second molding layer and a second redistribution layer. The second molding layer is disposed on the top surface of the second substrate, and a top surface of the first conductive pad is substantially coplanar with a top surface of the second molding layer. The second redistribution layer is disposed on the top surface of the second molding layer, and the first conductive pad is in contact with the second redistribution layer.

In an embodiment of the present disclosure, semiconductor device further includes an adhesive layer. The adhesive layer is disposed between the first semiconductor wafer and the second semiconductor wafer.

According to an embodiment of the present disclosure, a manufacturing method of a semiconductor device includes: forming at least one first conductive layer on a top surface of a first substrate; bonding a second substrate to the top surface of the first substrate; forming a first through hole penetrating through the second substrate; forming a first conductive via in the first through hole, such that the first conductive via extends from a top surface of the second substrate to the first conductive layer; and forming a first conductive pad on the top surface of the second substrate, such that the first conductive pad is in contact with the first conductive via.

In an embodiment of the present disclosure, the manufacturing method of a semiconductor device further includes: forming a recess into the first substrate; forming a second conductive via in the recess, in which the first conductive layer is in contact with the second conductive via; removing a bottom portion of the first substrate, such that the second conductive via is exposed; and forming a second conductive pad on a bottom surface of the first substrate, such that the second conductive via is in contact with the second conductive pad.

In an embodiment of the present disclosure, the manufacturing method of a semiconductor device further includes: forming a first molding layer on the bottom surface of the first substrate, wherein the second conductive pad is exposed by the first molding layer; and forming a first redistribution layer on a bottom surface of the first molding layer, such that the second conductive pad is in contact with the first redistribution layer.

In an embodiment of the present disclosure, the first semiconductor wafer includes a plurality of the first conductive layers, and the manufacturing method further includes: forming one of the first conductive layers on the top surface of the first substrate; forming a first interconnecting structure on the first conductive layer; and forming another first conductive layer on the first interconnecting structure.

In an embodiment of the present disclosure, the manufacturing method of a semiconductor device further includes: forming a second molding layer on the top surface of the second substrate, wherein the first conductive pad is exposed by the second molding layer; and forming a second redistribution layer on a top surface of the second molding layer, such that the first conductive pad is in contact with the second redistribution layer.

In an embodiment of the present disclosure, the manufacturing method of a semiconductor device further includes: forming at least one second conductive layer on a bottom surface of the second substrate; forming a second through hole penetrating through the second substrate; and forming a third conductive via in the second through hole, such that the third conductive via extends from the first conductive pad to the second conductive layer.

In an embodiment of the present disclosure, the second semiconductor wafer includes a plurality of the second conductive layers, and the manufacturing method further includes: forming one of the first conductive pads on the bottom surface of the second substrate; forming a second interconnecting structure on the first conductive pad; and forming another first conductive pad on the second interconnecting structure.

In an embodiment of the present disclosure, the manufacturing method of a semiconductor device further includes: forming a first dielectric layer on the first conductive layer; forming a second dielectric layer on the second conductive layer; bonding the first dielectric layer to the second dielectric layer; and heating the first dielectric layer and the second dielectric layer.

In the aforementioned embodiments of the present disclosure, since the second semiconductor wafer is disposed on the first semiconductor wafer, and the first conductive via extends from the first conductive pad of the second semiconductor wafer to the first conductive layer of the first semiconductor wafer, the semiconductor elements of the first semiconductor wafer and the semiconductor elements of the second semiconductor wafer can be electrically connected to each other through the first conductive via. In other words, the first conductive via 400 forms an interconnection between the first semiconductor wafer 200 and the second semiconductor wafer 300.

### BRIEF DESCRIPTION OF THE DRAWINGS

The disclosure can be more fully understood by reading the following detailed description of the embodiments, with reference made to the accompanying drawings as follows:

FIG. 1 is a cross-sectional view illustrating a semiconductor device according to an embodiment of the present disclosure;

FIG. 2 is a cross-sectional view illustrating a semiconductor device according to another embodiment of the present disclosure;

FIG. 3 is a flowchart illustrating a manufacturing method of a semiconductor device according to an embodiment of the present disclosure; and

FIGS. 4-22 are cross-sectional views of processes at various stages of a manufacturing method of a semiconductor device according to an embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

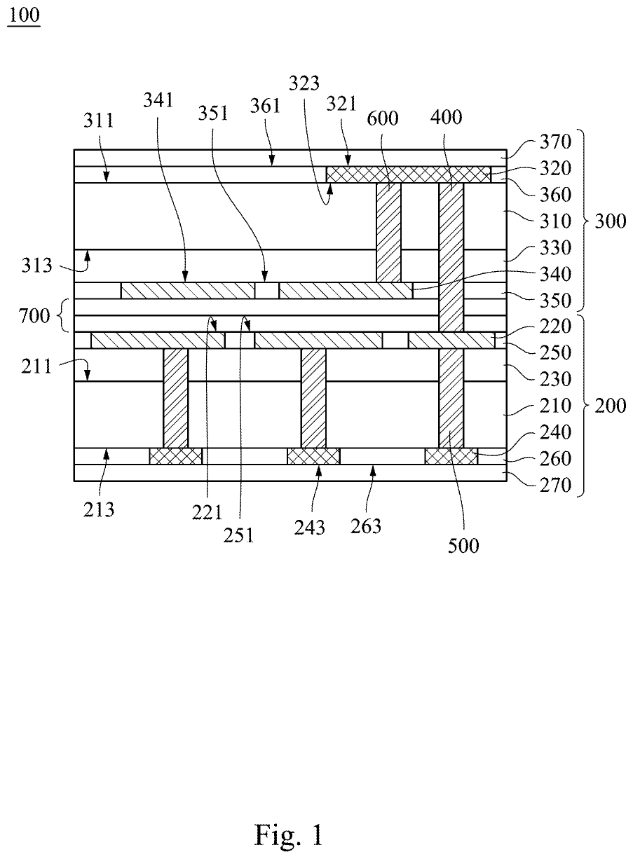

FIG. 1 is a cross-sectional view illustrating a semiconductor device 100 according to an embodiment of the present disclosure. The semiconductor device 100 includes a first semiconductor wafer 200, a second semiconductor wafer 300, and a first conductive via 400. The first semiconductor wafer 200 includes a first substrate 210 and at least one first conductive layer 220 disposed on a top surface of 211 the first substrate 210. The second semiconductor wafer 300 is disposed on the first semiconductor wafer 200. The second semiconductor wafer 300 includes a second substrate 310 and a first conductive pad 320 disposed on a top surface 311 of the second substrate 310. The first conductive via 400 extends from the first conductive pad 320 to the first conductive layer 220. In other words, the first conductive via 400 is between the first conductive layer 220 and the first conductive pad 320. In some embodiments, the first conductive layer 220 and the first conductive pad 320 may be made of a material including copper, and the first conductive via 400 may be made of a material including copper or tungsten, but the present disclosure is not limited in this regard.

In some embodiments, the first semiconductor wafer 200 further includes a first element layer 230. The first element layer 230 is disposed on the top surface of 211 the first substrate 210. Additionally, the second semiconductor wafer 300 further includes a second element layer 330. The second element layer 330 is disposed on a bottom surface 313 of the second substrate 310. Each of the first element layer 230 and the second element layer 330 includes at least one semiconductor element (not shown in the drawings).

Since the second semiconductor wafer 300 is disposed on the first semiconductor wafer 200, and the first conductive via 400 extends from the first conductive pad 320 of the second semiconductor wafer 300 to the first conductive layer 220 of the first semiconductor wafer 200, the first element layer 230 of the first semiconductor wafer 200 and the second element layer 330 of the second semiconductor wafer 300 can be electrically connected to each other through the first conductive via 400. In other words, the first conductive via 400 electrically connects the first element layer 230 and the second element layer 330 by forming an interconnection between the first semiconductor wafer 200 and the second semiconductor wafer 300.

In this embodiment, the first conductive layer 220 shown in FIG. 1 is disposed on the first element layer 230. In another embodiment, the first element layer 230 and the first conductive layer 220 may be disposed in the same layer. For example, the semiconductor element of the first element layer 230 may be next to the first conductive layer 220. Furthermore, the semiconductor element of the first element layer 230 is electrically connected to the first conductive layer 220 through traces (not shown in the drawings).

In some embodiments, the first semiconductor wafer 200 further includes a second conductive pad 240. The second conductive pad 240 is disposed on a bottom surface 213 of the first substrate 210. The semiconductor device 100 further includes a second conductive via 500. The second conductive via 500 extends from the first conductive layer 220 to the second conductive pad 240. In other words, the second conductive via 500 electrically connects the first conductive layer 220 and the second conductive pad 240. The second conductive pad 240 may be made of a material including copper, and the second conductive via 500 may be made of a material including copper or tungsten, but the present disclosure is not limited in this regard.

Since the semiconductor element of the first element layer 230 is electrically connected to the first conductive layer 220 through traces, and the first conductive layer 220 is electrically connected to the second conductive pad 240 through the second conductive via 500, the semiconductor element of the first element layer 230 is electrically connected to the second conductive pad 240 to make further electrical connections to other external semiconductor elements through various electrical structures, such as traces, wires, or conductive vias.

In some embodiments, the first semiconductor wafer 200 further includes a first insulating layer 250. The first insulating layer 250 is disposed on the top surface 211 of the first substrate 210, and a top surface 221 of the first conductive layer 220 is substantially coplanar with a top surface 251 of the first insulating layer 250. The first insulating layer 250 can protect the traces between the semiconductor element of the first element layer 230 and the first conductive layer 220, and further prevent shorting between the traces. Since the top surface 221 of the first conductive layer 220 is substantially coplanar with the top surface 251 of the first insulating layer 250, the first conductive via 400 can extend from a bottom surface 323 of the first conductive pad 320 to the top surface 221 of the first conductive layer 220 without being in contact with the first insulating layer 250.

In some embodiments, the first semiconductor wafer 200 further includes a first molding layer 260. The first molding layer 260 is disposed on the bottom surface 213 of the first substrate 210. Furthermore, a bottom surface 243 of the second conductive pad 240 is substantially coplanar with a bottom surface 263 of the first molding layer 260. The first molding layer 260 can protect the traces on the bottom surface 213 of the first substrate 210, and further prevent shorting between the traces. The first molding layer 260 may include the same material as the first insulating layer 250, but the present disclosure is not limited in this regard.

In some embodiments, the first semiconductor wafer 200 further includes a first redistribution layer 270. The first redistribution layer 270 is disposed on the bottom surface 263 of the first molding layer 260. Since the bottom surface 243 of the second conductive pad 240 is substantially coplanar with the bottom surface 263 of the first molding layer 260, the second conductive pad 240 is in contact with the first redistribution layer 270. The first redistribution layer 270 may be made of a material including metal, but the present disclosure is not limited in this regard.

In some embodiments, the second semiconductor wafer 300 further includes a second conductive layer 340. The second conductive layer 340 is disposed on the bottom surface 313 of the second substrate 310. The semiconductor device 100 further includes a third conductive via 600. The third conductive via 600 extends from the first conductive pad 320 to the second conductive layer 340. In other words, the third conductive via 600 electrically connects the first conductive pad 320 and the second conductive layer 340. The second conductive layer 340 may be made of a material including copper, and the third conductive via 600 may be made of a material including copper or tungsten, but the present disclosure is not limited in this regard.

In this embodiment, the second conductive layer 340 shown in FIG. 1 is disposed beneath the second element layer 330. In another embodiment, the second element layer 330 and the second conductive layer 340 may be disposed in the same layer. For example, the semiconductor element of the second element layer 330 may be next to the second conductive layer 340. Furthermore, the semiconductor element of the second element layer 330 is electrically connected to the second conductive layer 340 through traces (not shown in the drawings).

Since the semiconductor element of the second element layer 330 is electrically connected to the second conductive layer 340 through traces, and the second conductive layer 340 is electrically connected to the first conductive pad 320 through the third conductive via 600, the semiconductor element of the second element layer 330 is electrically connected to the first conductive pad 320 to make further electrical connections to other external semiconductor elements through various electrical structures, such as traces, wires, or conductive vias.

In some embodiments, the second semiconductor wafer 300 further includes a second insulating layer 350. The second insulating layer 350 is disposed on the bottom surface 313 of the second substrate 310, and a top surface 341 of the second conductive layer 340 is substantially coplanar with a top surface 351 of the second insulating layer 350. The second insulating layer 350 can protect the traces between the semiconductor element of the second element layer 330 and the second conductive layer 340, and further prevent shorting between the traces. Since the top surface 341 of the second conductive layer 340 is substantially coplanar with the top surface 351 of the second insulating layer 350, the third conductive via 600 can extend from the bottom surface 323 of the first conductive pad 320 to the top surface 341 of the second conductive layer 340 without being in contact with the second insulating layer 350.

In some embodiments, the second semiconductor wafer 300 further includes a second molding layer 360. The second molding layer 360 is disposed on the top surface 311 of the second substrate 310. Furthermore, a top surface 321 of the first conductive pad 320 is substantially coplanar with a top surface 361 of the second molding layer 360. The second molding layer 360 can protect the traces on the top surface 311 of the second substrate 310, and further prevent shorting between the traces. The second molding layer 360 may include the same material as the second insulating layer 350, but the present disclosure is not limited in this regard.

In some embodiments, the second semiconductor wafer 300 further includes a second redistribution layer 370. The second redistribution layer 370 is disposed on the top surface 361 of the second molding layer 360. Since the top surface 321 of the first conductive pad 320 is substantially coplanar with the top surface 361 of the second molding layer 360, the first conductive pad 320 is in contact with the second redistribution layer 370. The second redistribution layer 370 may be made of a material including metal, but the present disclosure is not limited in this regard.

In some embodiments, the semiconductor device 100 further includes an adhesive layer 700 having two dielectric layers. The adhesive layer 700 is disposed between the first semiconductor wafer 200 and the second semiconductor wafer 300, such that the first semiconductor wafer 200 is adhered to the second semiconductor wafer 300. Specifically, the adhesive layer 700 is disposed between the first semiconductor wafer 200 and the second semiconductor wafer 300 and in contact with the first conductive layer 220, the second conductive layer 340, the first insulating layer 250, and the second insulating layer 350. The adhesive layer 700 may be made of a material including dielectrics to prevent shorting between the first conductive layer 220 and the second conductive layer 340.

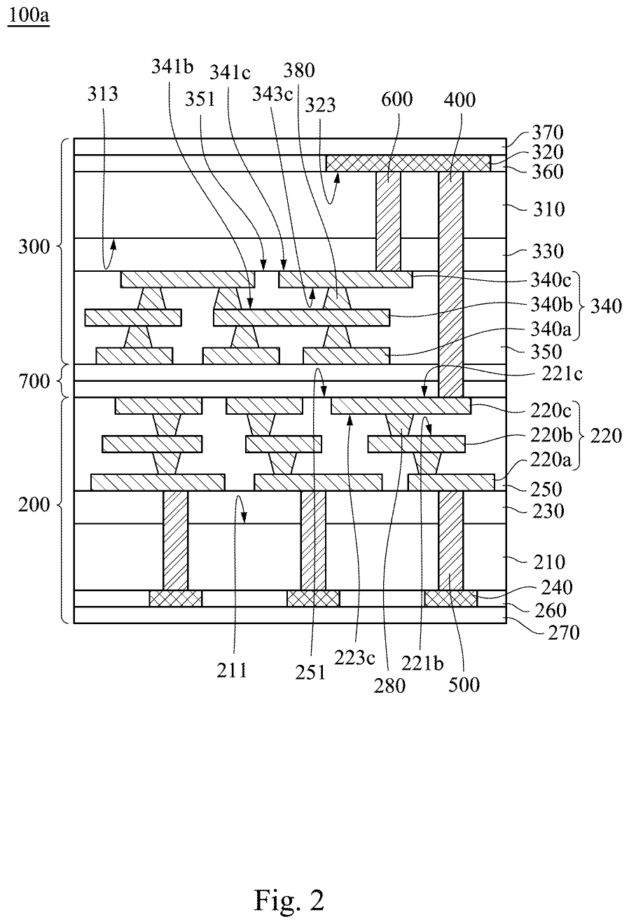

FIG. 2 is a cross-sectional view illustrating a semiconductor device 100a according to another embodiment of the present disclosure. The difference between the semiconductor device 100a and the semiconductor device 100 shown in FIG. 1 is that the semiconductor device 100a includes a plurality layers of the first conductive layers 220 and a plurality layers of the second conductive layers 340. Since some components of the semiconductor device 100 shown in FIG. 1 are similar to those corresponding components of the semiconductor device 100a shown in FIG. 2, descriptions for those similar components will not be repeated hereinafter. In the following description, the semiconductor device 100a will be discussed.

In the semiconductor device 100a, the first conductive layers 220 are stacked on the top surface 211 of the first substrate 210. For example, a middle first conductive layer 220b is disposed on the bottommost first conductive layer 220a, and a topmost first conductive layer 220c is disposed on the middle first conductive layer 220b. However, a number of layers of the first conductive layers 220 can be changed as deemed necessary by designers. Furthermore, a top surface 221c of the topmost first conductive layer 220c is substantially coplanar with the top surface 251 of the first insulating layer 250, such that the first conductive via 400 can extend from the bottom surface 323 of the first conductive pad 320 to the top surface 221c of the topmost first conductive layer 220c without being in contact with the first insulating layer 250.

In some embodiments, the first semiconductor wafer 220 further includes a plurality of first interconnecting structures 280 respectively disposed between two of the first conductive layers 200. The first interconnecting structures 280 respectively interconnect the first conductive layers 220. For example, one of the first interconnecting structures 280 extends from a bottom surface 223c of the topmost first conductive layer 220c to a top surface 221b of the middle first conductive layer 220b. The first interconnecting structures 280 may be made of a material including copper, but the present disclosure is not limited in this regard.

In some embodiments, the second conductive layers 340 are stacked on the bottom surface 313 of the second substrate 310. For example, a middle second conductive layer 340b is disposed on the bottommost second conductive layer 340a, and a topmost second conductive layer 340c is disposed on the middle second conductive layer 340b. However, a number of layers of the second conductive layers 340 can be changed as deemed necessary by designers. Furthermore, a top surface 341c of the topmost second conductive layer 340c is substantially coplanar with the top surface 351 of the second insulating layer 350, such that the third conductive via 600 can extend from the bottom surface 323 of the first conductive pad 320 to the top surface 341c of the topmost second conductive layer 340c without being in contact with the second insulating layer 350.

In some embodiments, the second semiconductor wafer 320 further includes a plurality of second interconnecting structures 380 respectively disposed between two of the second conductive layers 340. The second interconnecting structures 380 respectively interconnect the second conductive layers 340. For example, one of the second interconnecting structures 380 extends from a bottom surface 343c of the topmost second conductive layer 340c to a top surface 341b of the middle second conductive layer 340b. The second interconnecting structures 380 may be made of a material including copper, but the present disclosure is not limited in this regard.

In some embodiments, the adhesive layer 700 of the semiconductor device 100a is disposed between the first semiconductor wafer 200 and the second semiconductor wafer 300 and in contact with the topmost first conductive layer 220c, the bottommost second conductive layer 340a, the first insulating layer 250, and the second insulating layer 350. Furthermore, the adhesive layer 700 may prevent shorting between the topmost first conductive layer 220c and the bottommost second conductive layer 340a.

It is noted that the connection relationships, the materials, and the advantages of the elements described above will not be repeated. In the following description, a manufacturing method of the semiconductor device 100a will be discussed.

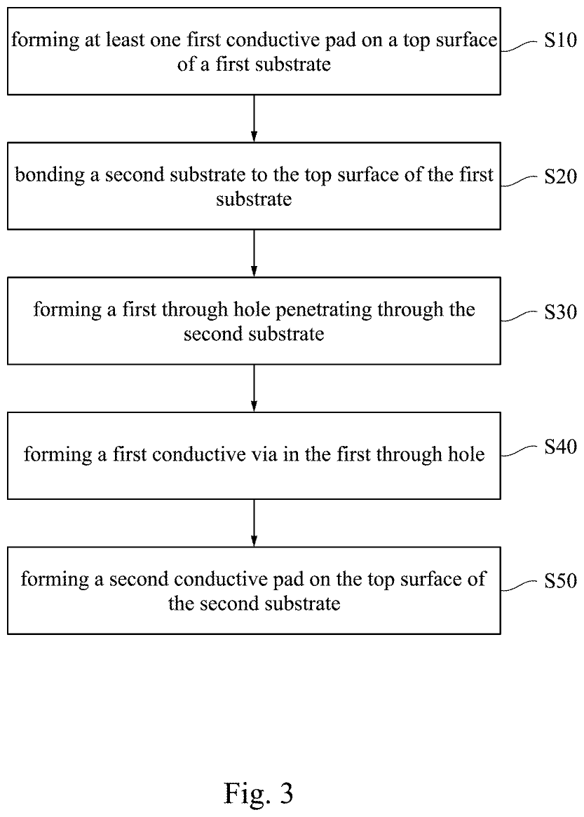

FIG. 3 is a flowchart illustrating the manufacturing method of the semiconductor device 100a according to an embodiment of the present disclosure. The manufacturing method of the semiconductor device 100a includes the following steps. In step S10, forming at least one first conductive layer on a top surface of a first substrate. In step S20, bonding a second substrate to the top surface of the first substrate. In step S30, forming a first through hole penetrating through the second substrate. In step S40, forming a first conductive via in the first through hole, such that the first conductive via extends from a top surface of the second substrate to the first conductive layer. In step S50, forming a first conductive pad on the top surface of the second substrate, such that the first conductive pad is in contact with the first conductive via. The aforementioned steps will be further discussed below.

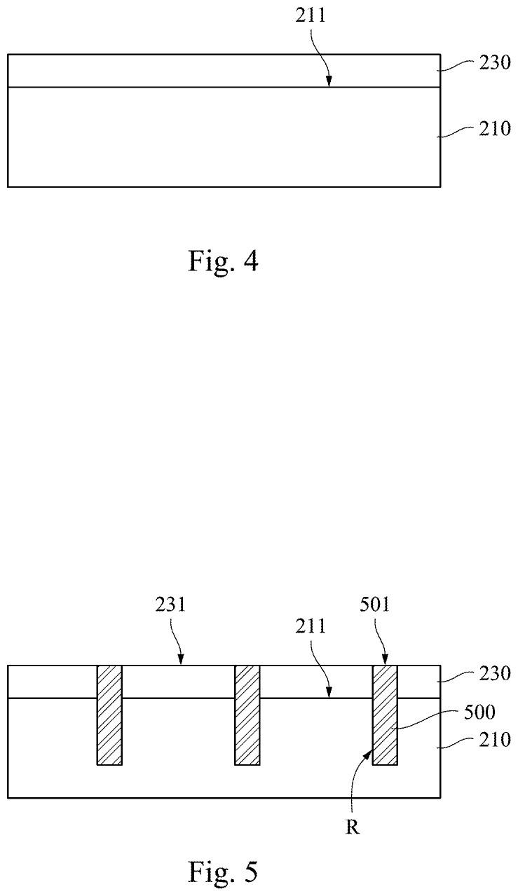

Reference is made to FIG. 4. The first substrate 210 is provided, and the first element layer 230 including the semiconductor element is formed on the top surface 211 of the first substrate 210.

Reference is made to FIG. 5. After the first element layer 230 is formed on the first substrate 210, a recess R is formed in the first substrate 210 and the first element layer 230. After that, the second conductive via 500 is formed in the recess R. In some embodiments, a planarization process may be performed such that a top surface 501 of the second conductive via 500 is substantially coplanar with a top surface 231 of the first element layer 230.

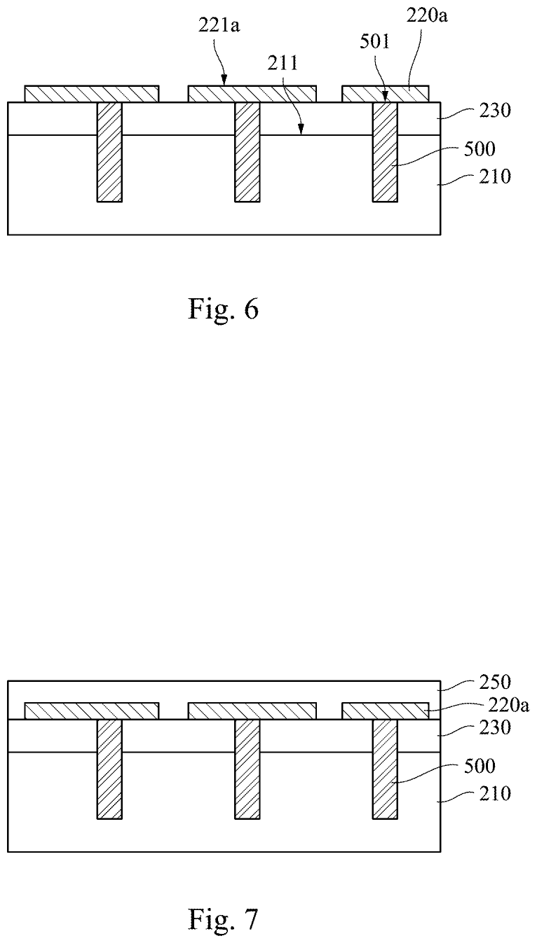

Reference is made to FIG. 6. After the second conductive via 500 is formed, the first conductive layer 220a is then formed on the top surface 211 of the first substrate 210 to be in contact with the top surface 501 of the second conductive via 500. In some embodiments, the first conductive layer 220a may be formed by deposition and etching. In alternative embodiments, the first conductive layer 220a may be formed by electroplating.

Reference is made to FIG. 7. After the first conductive layer 220a is formed, the first insulating layer 250 is formed to cover the conductive pad 220a and the first element layer 230.

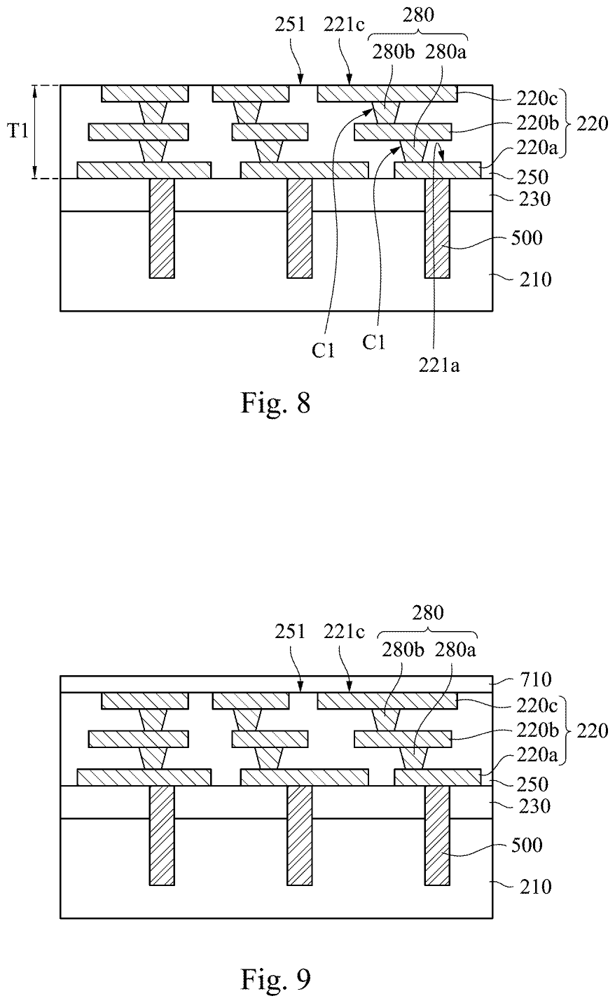

Reference is made to FIG. 8. A portion of the first insulating layer 250 on the first conductive layer 220a is then removed to form a cavity C1. In some embodiments, the first interconnecting structure 280a is then formed in the cavity C1 to be in contact with the top surface 221a of the first conductive layer 220a. After that, the first conductive layer 220b is further formed on the first interconnecting structure 280a. In alternative embodiments, the first interconnecting structure 280a and the first conductive layer 220b are integrally formed as a single piece without an interface therebetween. Thereafter, another portion of the first insulating layer 250 is formed over the first conductive layer 220b, and is then patterned to form another cavity C1 to expose a portion of the first conductive layer 220b. Next, in some embodiments, the first interconnecting structure 280b is formed on the exposed portion of the first conductive layer 220b and in the cavity C1, and the first conductive layer 220c is then formed on the first interconnecting structure 280b. In alternative embodiments, the first conductive layer 220c and the first interconnecting structure 280b are integrally formed as a single piece without an interface therebetween. Additionally, the thickness T1 of the first insulating layer 250 is associated with the number of the first conductive layers 220 and the number of the first interconnecting structures 280. Furthermore, the top surface 221c of the topmost first conductive layer 220c is substantially coplanar with the top surface 251 of the first insulating layer 250. Although FIG. 8 illustrates three first conductive layers 220 and two first interconnecting structures 280, the present disclosure is not limited in this regard.

Reference is made to FIG. 9. A first dielectric layer 710 is formed on the top surface 221c of the topmost first conductive layer 220c and the top surface 251 of the first insulating layer 250, such that the topmost first conductive layer 220c is covered by the first dielectric layer 710. In some embodiments, the first dielectric layer 710 may be made of a material including silicon oxide, silicon nitride, silicon oxynitride, or combinations thereof. In alternative embodiments, the first dielectric layer 710 may be made of a material including dielectrics with silicon oxide, silicon nitride, silicon oxynitride, or combinations thereof coated on its surface.

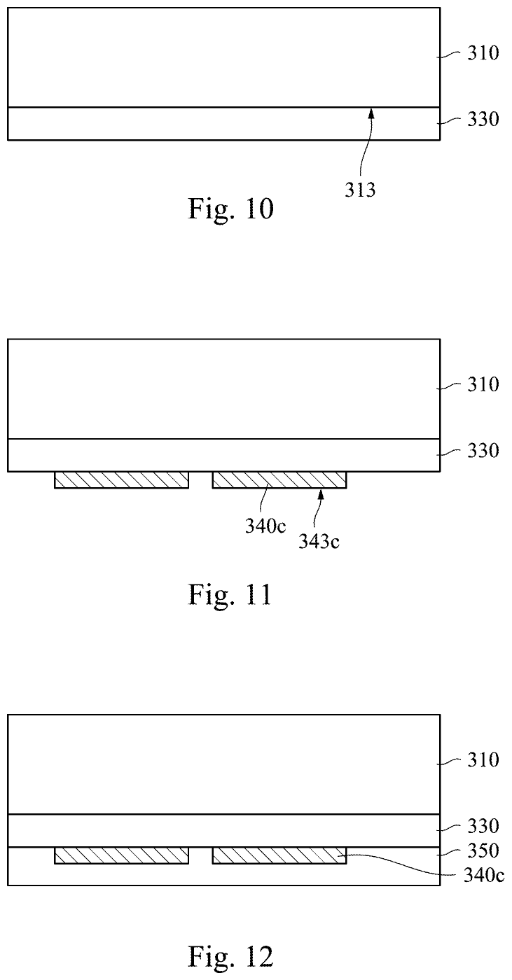

Reference is made to FIG. 10. The second substrate 310 is provided, and the second element layer 330 including the semiconductor element is formed on the bottom surface 313 of the second substrate 310.

Reference is made to FIG. 11. After the second element layer 330 is formed, the second conductive layer 340c is then formed on the second element layer 330. In some embodiments, the second conductive layer 340c may be formed by deposition and etching. In alternative embodiments, the second conductive layer 340c may be formed by electroplating.

Reference is made to FIG. 12. After the second conductive layer 340c is formed, the second insulating layer 350 is formed to cover the second conductive layer 340c and the second element layer 330.

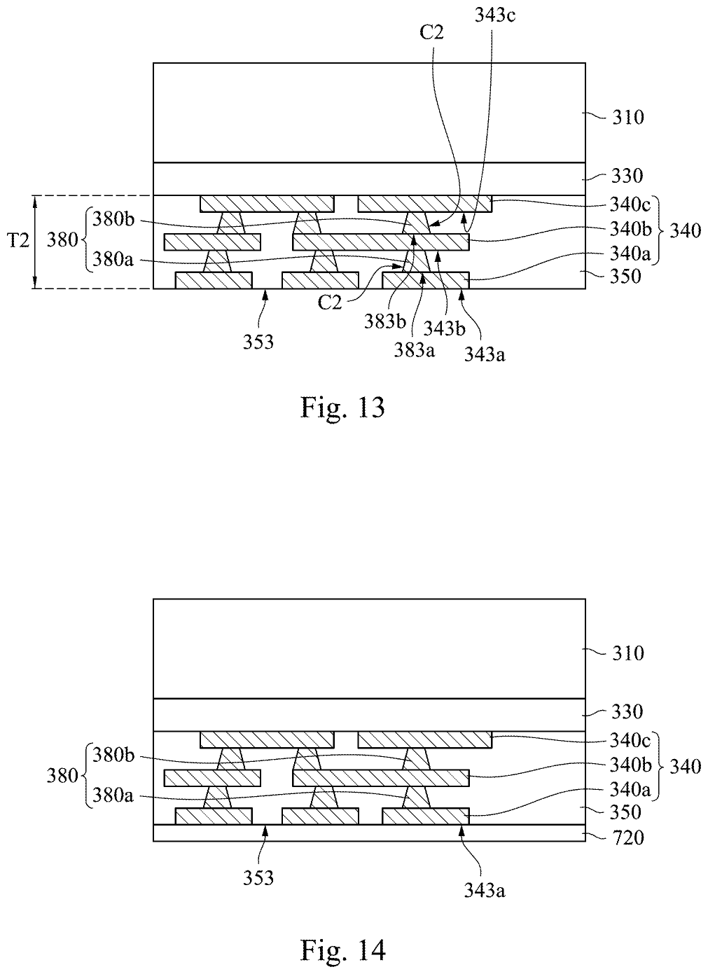

Reference is made to FIG. 13. A portion of the second insulating layer 350 on the bottom surface 343c of the second conductive layer 340c is then removed to form a cavity C2. In some embodiments, the second interconnecting structure 380b is then formed in the cavity C2 to be in contact with the bottom surface 343c of the second conductive layer 340c. After that, the second conductive layer 340b is further formed on the bottom surface 383b of the second interconnecting structure 380b. In alternative embodiments, the second interconnecting structure 380b and the second conductive layer 340c are integrally formed as a single piece without an interface therebetween. Thereafter, another portion of the second insulating layer 350 is formed over the second conductive layer 340b, and is then patterned to form another cavity C2 to expose a portion of the second conductive layer 340b. Next, in some embodiments, the second interconnecting structure 380a is formed on the exposed portion of the bottom surface 343b of the second conductive layer 340b and in the cavity C2, and the second conductive layer 340a is then formed on the bottom surface 383a of the second interconnecting structure 380a. In alternative embodiments, the second conductive layer 340a and the second interconnecting structure 380a are integrally formed as a single piece without an interface therebetween. Additionally, the thickness T2 of the second insulating layer 350 is associated with the number of the second conductive layers 340 and the number of the second interconnecting structures 380. Furthermore, the bottom surface 343a of the bottommost second conductive layer 340a is substantially coplanar with the bottom surface 353 of the second insulating layer 350. Although FIG. 13 illustrates three second conductive layer 340 and two second interconnecting structure 380, the present disclosure is not limited in this regard.

Reference is made to FIG. 14. A second dielectric layer 720 is formed on the bottom surface 343a of the bottommost second conductive layer 340a and the bottom surface 353 of the second insulating layer 350, such that the bottommost second conductive layer 340a is covered by the second dielectric layer 720. In some embodiments, the second dielectric layer 720 may be made of a material including silicon oxide, silicon nitride, silicon oxynitride, or combinations thereof. In alternative embodiments, the second dielectric layer 720 may be made of a material including dielectrics with silicon oxide, silicon nitride, silicon oxynitride, or combinations thereof coated on its surface.

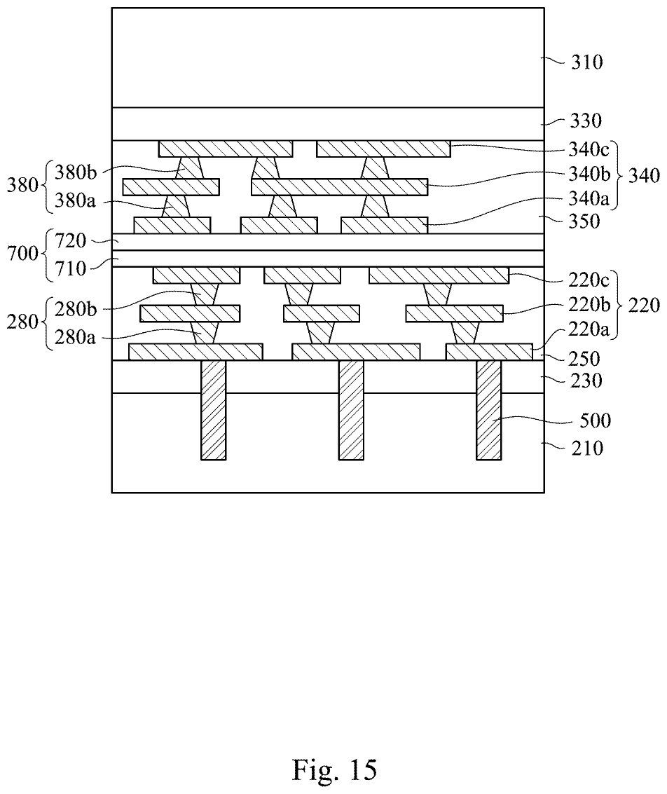

Reference is made to FIG. 15. In step S20 of FIG. 3, the structure of FIG. 14 is placed on top of the structure of FIG. 9, such that the first dielectric layer 710 is bonded to the second dielectric layer 720. Stated differently, the second substrate 310 is bonded to the first substrate 210 through the first dielectric layer 710 and the second dielectric layer 720. The first dielectric layer 710 and the second dielectric layer 720 are then heated, such that chemical bonds are formed between the material of the first dielectric layer 710 and the material of the second dielectric layer 720. For example, a chemical bond may be formed between the silicon element (Si) of the silicon oxide in the first dielectric layer 710 and the nitrogen element (N) of the silicon nitride in the second dielectric layer 720. As such, the first dielectric layer 710 is then adhered to the second dielectric layer 720 to form the adhesive layer 700.

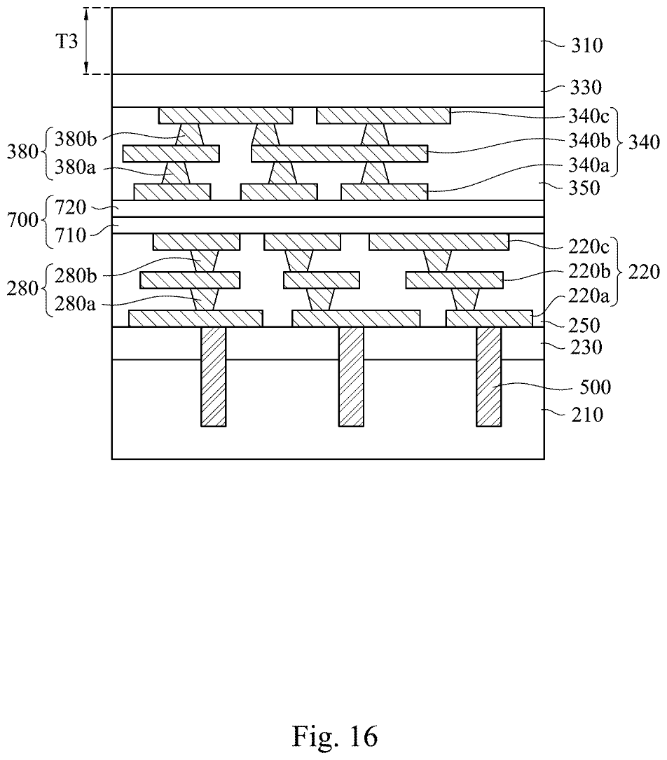

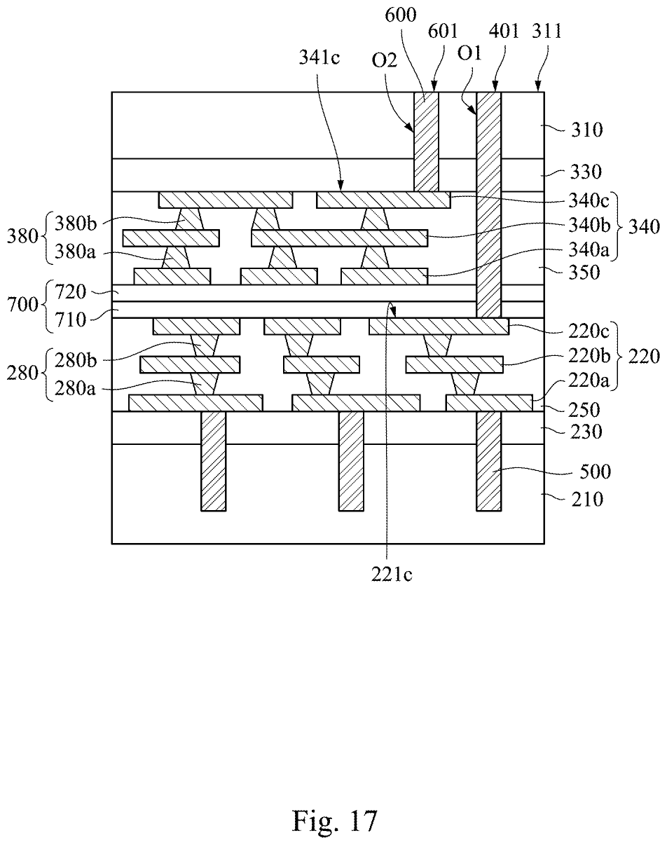

Reference is made to FIGS. 16 and 17. A planarization process (i.e., thinning or grinding process) is performed on a top portion of the second substrate 310, such that a thickness T3 of the second substrate 310 is decreased to a desired thickness. In step S30 of FIG. 3, a first through hole O1 is then formed to penetrate through the second substrate 310, the second insulating layer 350, the second dielectric layer 720, and the first dielectric layer 710, such that the topmost first conductive layer 220c is exposed from the first through hole O1. In step S40 of FIG. 3, the first conductive via 400 is then formed in the first through hole O1, such that the first conductive via 400 extends from the top surface 311 of the second substrate 310 to the top surface 221c of the topmost first conductive layer 220c. Moreover, a second through hole O2 is formed to penetrate through the second substrate 310, such that the topmost second conductive layer 340c is exposed from the second through hole O2. The third conductive via 600 is then formed in the second through hole O2, such that the second conductive via 500 extends from the top surface 311 of the second substrate 310 to the top surface 341c of the topmost second conductive layer 340c. A planarization process may be performed such that a top surface 401 of the first conductive via 400 and a top surface 601 of the third conductive via 600 is substantially coplanar with the top surface 311 of the second substrate 310. In some embodiments, the first conductive via 400 and the third conductive via 600 may include the same material.

The first through hole O1 and the first conductive via 400 may be formed after or before the second through hole O2 and the third conductive via 600 are formed. In alternative embodiments, the first conductive via 400 and the third conductive via 600 may be formed simultaneously after the first through hole O1 and the second through hole O2 are formed.

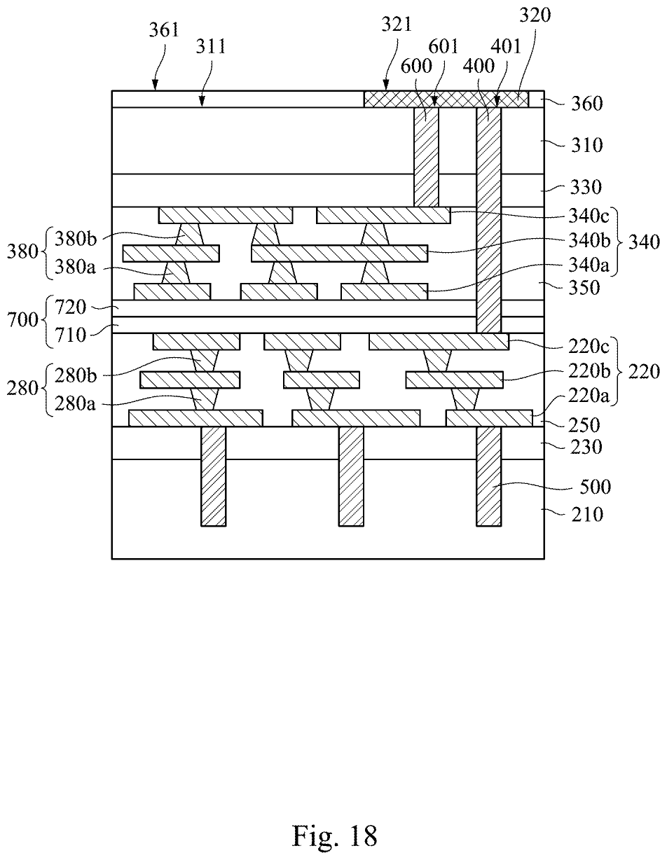

Reference is made to FIG. 18. In step S50 of FIG. 3, the first conductive pad 320 is formed on the top surface 311 of the second substrate 310 to be in contact with the top surface 401 of the first conductive via 400 and the top surface 601 of the third conductive via 600. The second molding layer 360 is then formed on the top surface 311 of the second substrate 310 to surround the first conductive pad 320. In some embodiments, the first conductive pad 320 may be formed by deposition and etching. In alternative embodiments, the first conductive pad 320 may be formed by electroplating. Furthermore, a planarization process may be performed such that a top surface 321 of the first conductive pad 320 is substantially coplanar with the top surface 361 of the second molding layer 360. Stated differently, the first conductive pad 320 is exposed by the second molding layer 360.

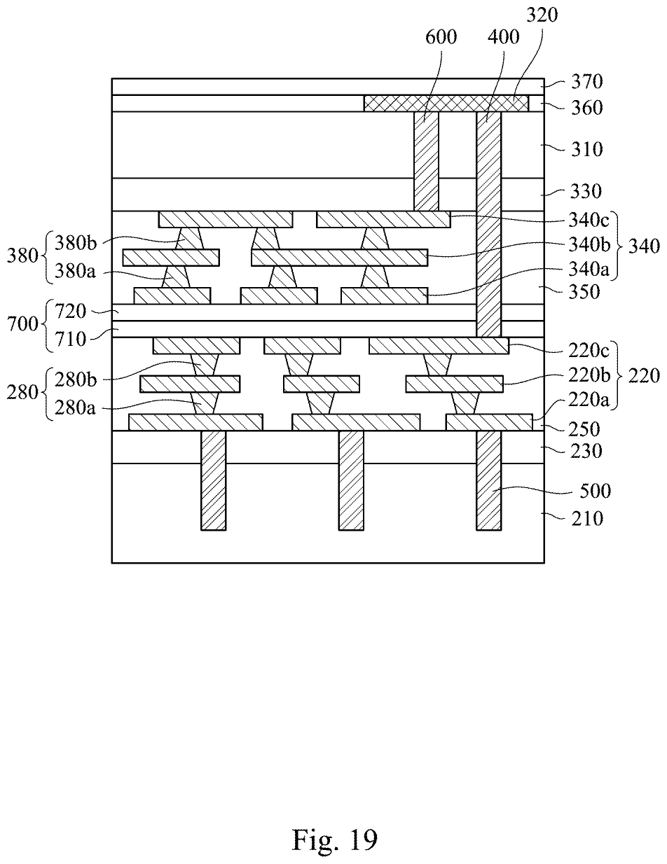

Reference is made to FIG. 19. After the second molding layer 360 and the first conductive pad 320 are formed, the second redistribution layer 370 is formed on the second molding layer 360 and in contact with the first conductive pad 320.

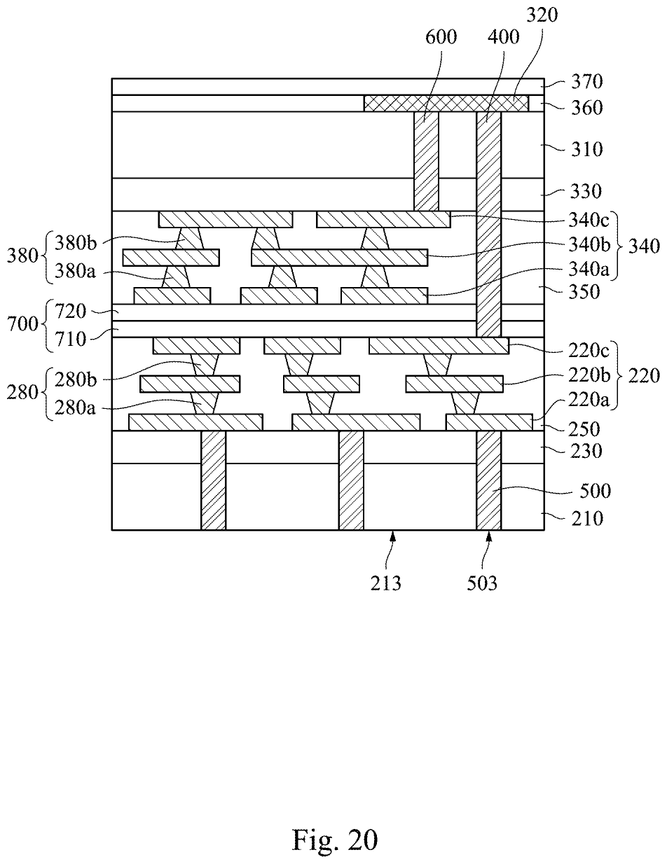

Reference is made to FIG. 20. A planarization process is performed such that a bottom portion of the first substrate 210 is removed, and the second conductive via 500 is exposed by the bottom surface 213 of the first substrate 210. Furthermore, the bottom surface 503 of the second conductive via 500 is substantially coplanar with the bottom surface 313 of the second substrate 310.

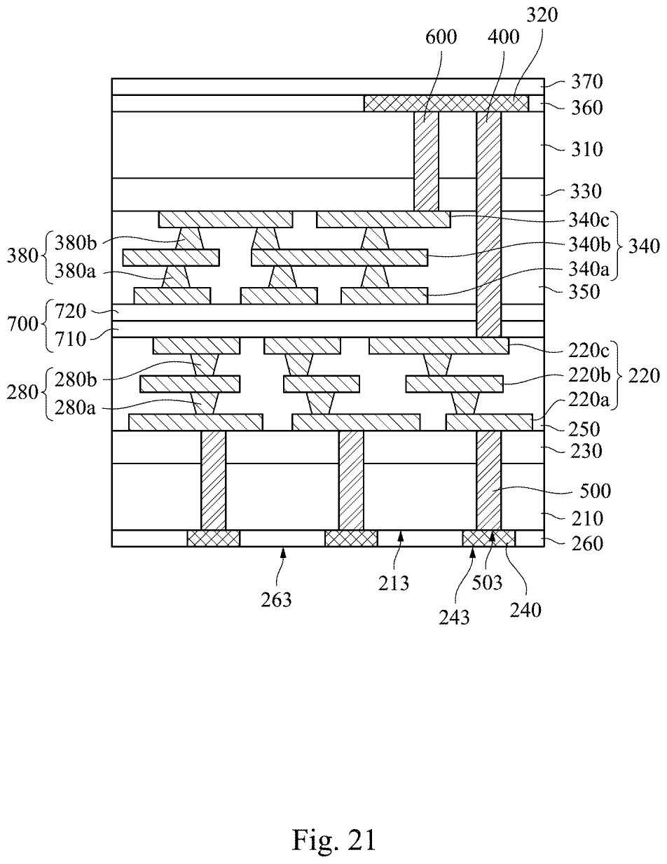

Reference is made to FIG. 21. The second conductive pad 240 is formed on the bottom surface 213 of the first substrate 210 to be in contact with the bottom surface 503 of the second conductive via 500. The first molding layer 260 is then formed on the bottom surface 213 of the first substrate 210 to surround the second conductive pad 240. In some embodiments, the second conductive pad 240 may be formed by deposition and etching. In alternative embodiments, the second conductive pad 240 may be formed by electroplating. Furthermore, a planarization process may be performed such that the bottom surface 243 of the second conductive pad 240 is substantially coplanar with the bottom surface 263 of the first molding layer 260. Stated differently, the second conductive pad 240 is exposed by the first molding layer 260.

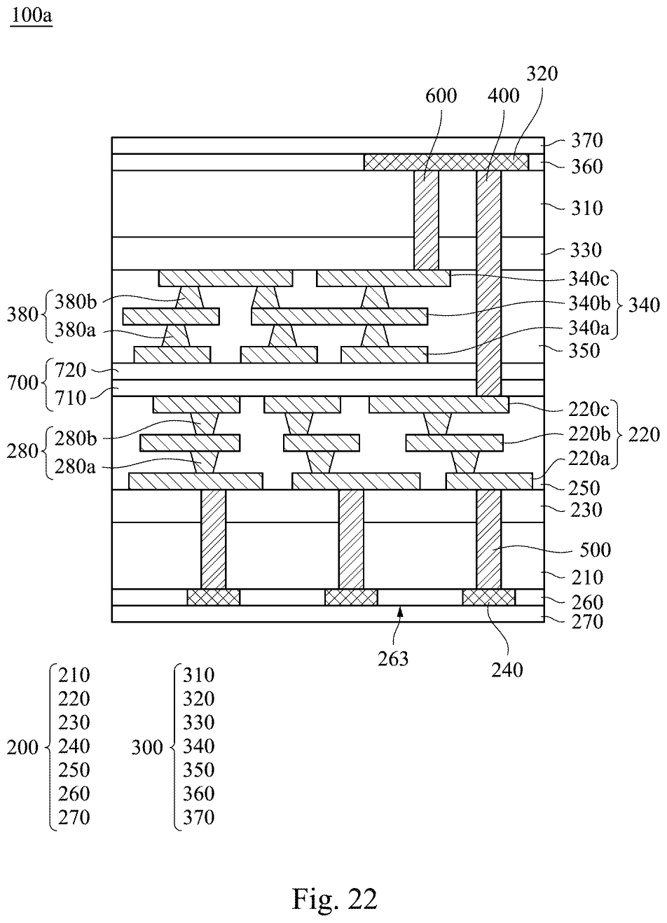

Reference is made to FIG. 22. After the first molding layer 260 and the second conductive pad 240 are formed, the first redistribution layer 270 is formed on the bottom surface 263 of the first molding layer 260 and in contact with the first molding layer 260. After the aforementioned stages, the semiconductor device 100a including the first semiconductor wafer 200 and the second semiconductor wafer 300 that is on the first semiconductor wafer 200 can be obtained.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

1. A semiconductor device, comprising:
a first semiconductor wafer comprising:
a first substrate; and
at least one first conductive layer disposed on a top surface of the first substrate;
a second semiconductor wafer disposed on the first semiconductor wafer, wherein the second semiconductor wafer comprises:
a second substrate; and
a first conductive pad disposed on a top surface of the second substrate; and
a first conductive via extending from the first conductive pad to the first conductive layer.

2. The semiconductor device of claim 1, wherein the first semiconductor wafer further comprises:
a first insulating layer disposed on the top surface of the first substrate, wherein a top surface of the first conductive layer is substantially coplanar with a top surface of the first insulating layer.

3. The semiconductor device of claim 1, wherein the first semiconductor wafer further comprises a second conductive pad disposed on a bottom surface of the first substrate, and the semiconductor device further comprises:
a second conductive via extending from the first conductive layer to the second conductive pad.

4. The semiconductor device of claim 3, wherein the first semiconductor wafer further comprises:
a first molding layer disposed on the bottom surface of the first substrate, wherein a bottom surface of the second conductive pad is substantially coplanar with a bottom surface of the first molding layer; and
a first redistribution layer disposed on the bottom surface of the first molding layer, wherein the second conductive pad is in contact with the first redistribution layer.

5. The semiconductor device of claim 1, wherein the first semiconductor wafer comprises a plurality of the first conductive layers, and the first conductive layers are stacked on the top surface of the first substrate.

6. The semiconductor device of claim 5, wherein the first semiconductor wafer further comprises:
a plurality of first interconnecting structures disposed between the first conductive layers, respectively.

7. The semiconductor device of claim 1, wherein the second semiconductor wafer further comprises at least one second conductive layer disposed on a bottom surface of the second substrate, and the semiconductor device further comprises:
a third conductive via extending from the first conductive pad to the second conductive layer.

8. The semiconductor device of claim 7, wherein the second semiconductor wafer further comprises:
a second insulating layer disposed on the bottom surface of the second substrate, wherein a bottom surface of the second conductive layer is substantially coplanar with a bottom surface of the second insulating layer.

9. The semiconductor device of claim 7, wherein the second semiconductor wafer comprises a plurality of the second conductive layers, and the second conductive layers are stacked on the bottom surface of the second substrate.

10. The semiconductor device of claim 9, wherein the second semiconductor wafer further comprises:
a plurality of second interconnecting structures disposed between the second conductive layers, respectively.

11. The semiconductor device of claim 1, wherein the second semiconductor wafer further comprises:
a second molding layer disposed on the top surface of the second substrate, wherein a top surface of the first conductive pad is substantially coplanar with a top surface of the second molding layer, and
a second redistribution layer disposed on the top surface of the second molding layer, wherein the first conductive pad is in contact with the second redistribution layer.

12. The semiconductor device of claim 1, further comprising:
an adhesive layer disposed between the first semiconductor wafer and the second semiconductor wafer.

13-20. (canceled)
